(19) United States
(12) Patent Application Publication
(10) Pub. No.: US 2004/0200416 A1
(43) Pub. Date: Oct. 14, 2004

(54) Effusion cell with improved temperature control of the crucible

(76) Inventors: Heiko Schuler, Grafenau (DE); Karl Eberl, Berlin (DE); Frank Huber, Weil der Stadt (DE)

Correspondence Address: MBE-Komponenten, attn: Heiko Schuler, Gutenbergstrasse 8, Weil der Stadt, DE, 71263, US

(21) Appl. No.: 10/817,868

(22) Filed: Apr. 6, 2004

(30) Foreign Application Priority Data
Apr. 9, 2003 (DE) 103 16 228.3

(51) Int. Cl. C23C 16/00

(52) U.S. Cl. 118/723 E

(57) ABSTRACT

The temperature coupling of crucible (4) of an effusion cell to a receiving part (1) that surrounds the crucible (4) and serves as a heating-equipped cooling reservoir is improved by inserting, in the space (2) between the crucible (4) and the wall of a recess (1A) in the receiving part (1), a conducting medium with high heat conductivity and low vapor pressure (e.g. Ga, In, Hg or a soft solid). As a result of the improved thermal coupling of crucible (4), the temperature of the crucible (4) follows more rapidly that of the heating-equipped cooling reservoir, such that materials with high vapor pressure and relatively low evaporation temperatures can be deposited under greater control.

### BACKGROUND OF THE INVENTION

This invention concerns an effusion cell for the vapor deposition method and an application of this effusion cell to a vapor deposition method, especially for vapor deposition of organic materials or materials with comparably high vapor pressure.

The invention relates to the field of fabricating thin layers by vapor deposition of a chosen material onto a substrate under vacuum to ultrahigh vacuum conditions. Such vapor deposition processes are carried out mainly in semiconductor engineering but also with other materials, using molecular beam epitaxy. In the appropriate evaporation devices, so-called effusion cells are used to generate a molecular beam of the chosen material. In these, a crucible containing the substance to be evaporated is heated to a particular temperature and the stream of evaporating material leaves the cell through a relatively narrow aperture in the ultrahigh vacuum. This material can then be directed, as a molecular or atomic beam, at the surface to be coated.

Relatively accurate control of the crucible's temperature is very important for controlled deposition. For that reason, effusion cells are usually provided with a temperature regulator in which the crucible's temperature is sensed by a thermoelement and temperature fluctuations converted into a control signal for regulating a heating current.

For the most commonly used, relatively high effusion cell operating temperatures of several hundred to over one thousand degrees Celsius, the conventional method of radiant heating and radiant cooling of the crucible provides sufficiently stable operating conditions.

However, it has proved very difficult to carry out highly controlled deposition of materials with high vapor pressure which evaporate or undergo sublimation at room temperature or at up to approx. 200° C. (e.g. organic materials), since heat transfer between the crucible and the heating-equipped cooling reservoir usually takes place mainly through the exchange of radiant heat, and therefore at low temperatures the temperature of the crucible only very slowly follows that of the reservoir. As a result, stable temperature conditions are only very slowly reached in the crucible.

Nevertheless, it is desirable to evaporate these materials thermally from a crucible or some other inert container by means of accurate temperature control, thus also making possible controlled layer growth of these materials. However, it is difficult to couple such crucibles in vacuum across a large area to a heating and cooling reservoir, especially if they consist of quartz glass or ceramics. As a result of the crucible's poor coupling, its cooling time in vacuum is lengthy, such that accurate temperature regulation to within 0.1° C. is extremely difficult. Temperature measurement itself is a further difficulty, since the temperature sensor cannot be firmly attached to the crucible in a straightforward manner.

Therefore, the task of the present invention is to provide an effusion cell with improved temperature control, with which vapor deposition processes can be carried out in the low temperature range for materials with high vapor pressure.

This task is accomplished by means of the features described in patent claim 1 with regard to an effusion cell and in patent claim 11 with regard to a vapor deposition method. Advantageous further designs and embodiments form the subject of sub-claims.

### SUMMARY OF THE INVENTION

An essential idea of the present invention consists of filling the space that exists in an effusion cell between the crucible and a receiving part that serves as a heating-equipped cooling reservoir with a gas, a liquid or a plastically deformable solid material to act as a conducting medium. The conducting medium replaces the radiant heat transport, which is inefficient at low temperatures, with heat conduction, and ensures that the crucible takes on the temperature set by the heating-equipped cooling reservoir without a long delay period.

The heating-equipped cooling reservoir is a device in which, for the purpose of better regulation and faster response to required temperature changes, it is possible simultaneously to heat and counter-cool, in order to finally set a crucible temperature between that of the heater and that of the cooling medium. Additionally, it is possible by only heating to set a comparatively high crucible temperature or by only cooling to set a low crucible temperature.

With the heating-equipped cooling reservoir, the crucible can also, for example, be set to a temperature in the vicinity of or below room temperature, and by means of a temperature sensor and a regulator the set temperature can be accurately regulated.

The receiving part is, for example, a material block, which preferably has high heat conductivity and contains a recess for holding the crucible. For example, the receiving part can be made of metal or a ceramic. It can be designed as a cooling reservoir, for example, by having cooling pipes embedded in it which are flooded with water or a cooling medium. Alternatively, the receiving part can also be merely coupled thermally to a suitably-designed primary cooling reservoir, such that it does not itself contain cooling pipes. The receiving part can then contain a heating device, designed, for example, in the form of a heating wire, which is embedded in the receiving part. Further the receiving part can also be merely coupled thermally to a suitably-designed primary heating device so that it does not contain a heating wire it self. By means of the heating device and the cooling reservoir, the temperature of the receiving part can be adjusted as needed within certain limits, with a thermoelement embedded in the receiving part immediately next to the crucible and a temperature regulator linked to it ensuring that the chosen temperature value is maintained. This value can also lie close to room temperature or even below it, such that controlled evaporation of materials with high vapor pressure at relatively low temperatures (e.g. organic materials) can also be made possible.

The recess formed in the material block or in the receiving part and/or the crucible can, in principle, take on arbitrary shapes. However, in a manner which is well-known per se, round vessel shapes which in cross-section are circular or elliptical and whose longitudinal section is parabola-shaped are advantageous. The recess and the crucible can have such shapes and dimensions that they are essentially congruent with each other, such that although a space is not nominally part of the design, due to inaccuracies in the components' dimensions, changes in the relative positions of the components to each other that result from the crucible's fixing or roughness in the materials' surfaces, it is always present in practice. The design can also be such that the recess and the crucible are shaped and have such dimensions so as not to be congruent with each other, with a space being deliberately formed between them, for example in order to contribute to a spatially homogeneous heat transfer between the receiving part and the crucible. This space can, for example, extend from the bottom area along the wall of the crucible cylinder symmetrically to the cylindrical axis of the crucible and the recess up to a specified height. The space can also extend up to the upper edge of the recess.

The space can be open or closed on all sides. The conducting medium contained in the space cannot escape from it, because of its low vapor pressure and/or because of the tight sealing of the space. The sealing can be assured by the crucible having a surrounding collar, in a manner conventional per se, which lies upon an edge section of the recess in the receiving part. By fixing the collar to the edge section, the space can be hermetically sealed if desired.

Preferably, the heat conducting medium poured into the space has low vapor pressure and good heat conductivity, in order to have optimum thermal coupling between the crucible and its heated and cooled surroundings. It can be a suitable gas, liquid or a soft solid material. Possible choices include, for example, gallium, indium, mercury and their alloys, oils, silicon oils and fats with a high boiling point, metallic textile or wool, or other materials comparable with the aforementioned materials insofar as they have, in order of magnitude terms, a comparable or lower vapor pressure under vacuum to ultrahigh vacuum conditions. The choice of such materials is advantageous, since then the space does not have to be hermetically sealed during operation. The tighter the space is sealed, the less stringent are the requirements with regard to the conducting medium's vapor pressure.

### BRIEF DESCRIPTION OF THE DRAWING

FIG. 1 is a cross sectional schematic view of the side of the heating-equipped cooling reservoir, the crucible and the space between according to the present invention.

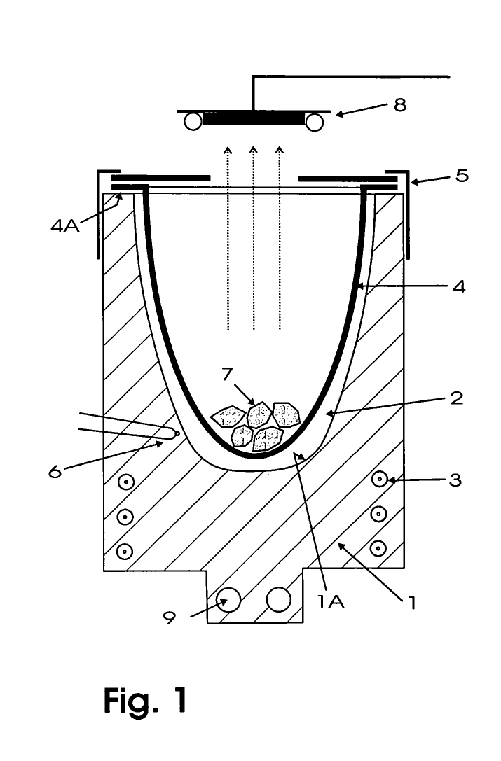

### DETAILED DESCRIPTION OF THE INVENTION

A block of material 1, made from a material with good heat conductivity, e.g. metal or a suitable ceramic, has a round recess 1A in which a crucible 4 is inserted. The longitudinal section shows that the recess and the crucible are round vessels, i.e. that both the wall of recess 1A and the wall of crucible 4 are parabola shaped, with crucible 4 having a slightly smaller diameter and a slightly smaller depth than recess 1A, such that a space 2 is created between the wall of crucible 4 and the wall of recess 1A.

Crucible 4 contains the substance 7 to be evaporated, which in its initial state can be a solid or a liquid.

The material block 1 is thermally coupled to a cooling reservoir 9, such that without heating it is at a relatively low temperature determined by the water- or coolant-cooled reservoir 9. The material block 1 contains an embedded heating device e.g. in the form of a spiral heating wire 3, e.g. made of tantalum, through which the temperature of material block 1 can be adjusted. Using a thermoelement 6, which is embedded in the material block 1 and is located relatively close to crucible 4, the temperature of material block 1 can be measured and appropriately regulated.

Crucible 4 has an upper collar 4A, and by means of it lies on top of an upper edge section of the recess 1A. A crucible fixing 5 ensures that the collar 4A is firmly connected with the material block 1, such that the space 2 is more or less tightly sealed, where a sealing medium such as a sealing ring (not shown) may be inserted between the collar 4A and the edge section in a suitable place. The space 2 can also, if desired, be hermetically sealed by the crucible fixing 5.

Space 2 is filled in whole or in part with a heat conducting medium. The latter should have a high heat conductivity and a low vapor pressure, such that the conducting medium cannot escape into the evacuated surroundings. In the embodiment example shown, the space 2 extends from a bottom region of the crucible 4 and the recess 1A with cylindrical symmetry along the wall of the crucible 4 and the wall of the recess 1A up to the upper edge of the recess 1A. Alternatively, it can also be arranged to have the space 2 extend only up to a particular height of the crucible 4, and from this height have the wall of the crucible 4 attached directly to the wall of the recess 1A.

A swiveling or folding lid 8 is also allowed for, through which crucible 4 can be closed vacuum-tight.

1. Effusion cell for a vapor deposition method, with
a crucible (4) for a substance to be evaporated (7),
a receiving part designed as a heating-equipped cooling reservoir (1) with a recess (1A) for receiving the crucible (4), where
a space (2) between the recess (1A) and the crucible (4) is filled at least in part with a gas, a liquid or a plastically deformable solid object as a heat-conducting medium.

2. Effusion cell as per claim 1, characterized in that
the receiving part (1) itself is designed as a cooling reservoir or is thermally coupled to a primary cooling reservoir, and
the receiving part (1) contains a heating device (3).

3. Effusion cell as per claim 2, characterized in that
the heating device (3) is designed as a heating wire (3) embedded in the receiving part (1) and in particular runs spirally around the recess (1A).

4. Effusion cell as per one of the preceding claims, characterized in that
the receiving part (1) is designed as a material block (1).

5. Effusion cell as per one of the preceding claims, characterized in that
the receiving part (1) is made of metal or a ceramic.

6. Effusion cell as per one of the preceding claims, characterized in that
the recess (1A) and the crucible (4) are shaped as essentially congruent to each other.

7. Effusion cell as per one of the preceding claims, characterized in that
the recess (1A) and the crucible (4) are shaped as essentially non-congruent to each other.

8. Effusion cell as per one of the preceding claims, characterized in that
the crucible (4) has a surrounding collar (4A), which lies on top of an edge section of the recess (1A).

9. Effusion cell as per one of the preceding claims, characterized in that
the space (2) contains Ga, In, Hg or is filled with a substance that has a vapor pressure of an order of magnitude that is comparable to or lower than that of Ga, In or Hg under vacuum to ultrahigh vacuum conditions.

10. Effusion cell as per one of the preceding claims, characterized in that
a temperature sensor (6), especially a thermoelement (6), is embedded in the receiving part (1).

11. Vapor deposition method with an effusion cell which has
a crucible (4) for receiving a substance to be evaporated (7), and
a receiving part (1) designed as a heating-equipped cooling reservoir, especially a material block (1), with a recess (1A) for receiving the crucible (4), where
a space between the receiving part (1) and the crucible (4) is filled at least in part with a gas, a liquid or a plastically deformable solid acting as a heat-conducting medium.

12. Method as per claim 11, in which the space (2) contains Ga, In, Hg or is filled with a substance that has a vapor pressure of an order of magnitude that is comparable to or lower than that of Ga, In or Hg under vacuum to ultrahigh vacuum conditions.
